(19) United States
(12) Patent Application Publication
(10) Pub. No.: US 2007/0114573 A1
(43) Pub. Date: May 24, 2007

(54) Sensor device with heated nanostructure

(76) Inventors: Tzong-Ru Han, Cambridge, MA (US); Alexander Star, Albany, CA (US); Philip G. Collins, Irvine, CA (US); Jean-Christophe P. Gabriel, Pinole, CA (US); George Gruner, Los Angeles, CA (US); Keith Bradley, New York, NY (US)

Correspondence Address: O'MELVENY & MYERS LLP, 610 NEWPORT CENTER DRIVE, 17TH FLOOR, NEWPORT BEACH, CA, 92660, US

(21) Appl. No.: 10/655,529

(22) Filed: Sep. 4, 2003

Related U.S. Application Data
(60) Provisional application No. 60/408,362, filed on Sep. 4, 2002.

(51) Int. Cl. H01L 29/768

(52) U.S. Cl. 257/226

(57) ABSTRACT

A nanostructure sensing device includes a substrate, a nanotube disposed over the substrate, and at least two conductive elements electrically connected to the nanotube. A electric current on the order of about 10 μA, or greater, is passed through the conductive elements and the nanotube. As a result, the nanotube heats up relative to the substrate. In the alternative, some other method may be used to heat the nanotube. When operated as a sensor with a heated nanotube, the sensor's response and/or recovery time may be markedly improved.

### CROSS-REFERENCE TO RELATED APPLICATION

This application claims priority pursuant to 35 U.S.C. § 119(e) to U.S. Provisional Application No. 60/408,362, filed Sep. 4, 2002, which application is specifically incorporated herein, in its entirety, by reference.

### BACKGROUND OF THE INVENTION

1. Field of the Invention

The present invention relates to sensors and other devices made from nanostructures, such as nanotubes.

2. Description of Related Art

Nanotube transistors and resistors can be fabricated on silicon substrates. These devices are made by growing nanotubes by chemical vapor deposition directly on the substrates, although they can also be made by other methods known in the art, such as by growing nanotubes by laser ablation or chemical vapor deposition elsewhere and then placing then on the substrates. Subsequently, electrodes, such as metal wires, are patterned onto the substrate to connect the nanotubes into circuits.

Nanotube devices may be used as chemical sensors. For such applications, a passivation material may be used to cover only the metal contacts, leaving a segment of nanotubes exposed. Alternatively, the passivation can cover the nanotubes entirely. Such devices have been shown to respond to hydrogen, among other things. Such response may deteriorate with time. It is desirable, however, to restore and/or to increase the sensitivity and responsiveness of nanotube devices to hydrogen and to other materials.

### SUMMARY OF THE INVENTION

The present invention provides a nanotube device with improved responsiveness to hydrogen and other materials. Surprisingly, it was found that the responsiveness of a nanotube sensor may be greatly enhanced by heating the nanotube independently of the substrate to which it is attached. This may be accomplished, for example, by ohmic heating. The device substrate should have a temperature not greater than about 100° C. The nanotube or nanotubes attached to the substrate should have a temperature substantially greater than 100° C., such as, for example, about 300° C. When operated in this condition, a nanotube sensor exhibits a much faster response to sensor targets such as hydrogen.

A more complete understanding of the nanotube device will be afforded to those skilled in the art, as well as a realization of additional advantages and objects thereof, by a consideration of the following detailed description of the preferred embodiment. Reference will be made to the appended sheets of drawings which will first be described briefly.

### BRIEF DESCRIPTION OF THE DRAWINGS

FIG. 1 is a diagram showing an exemplary nanostructure sensing device according to the invention.

FIGS. 2a and 2b show response of a tin oxide functionalized nanotube sensor to three short exposures to hydrogen at 200° C. on a hot plate (a) at low current and (b) at high current.

FIGS. 3a and 3b show response of a Pd-decorated nanotube sensor to short exposures to hydrogen (a) after production and (b) after several days at ambient conditions.

FIGS. 3c and 3d show regeneration of the Pd-decorated sensor by (c) heating to 100° C. on a hot plate and by (d) passing 4 mA current through the device at room temperature.

### DETAILED DESCRIPTION OF THE PREFERRED EMBODIMENT

The present invention provides a method and structure for improving and/or restoring the response time of a nanostructure sensor device.

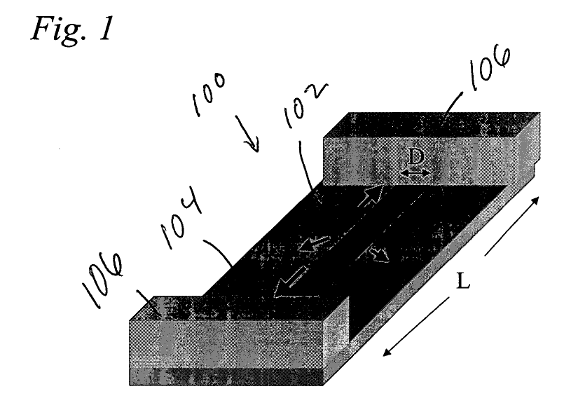

Nanostructure sensing devices can be heated by passing a current through the nanotubes, so-called ohmic heating. The benefit provided by this technique is that much less power is required to maintain a section of nanotube at hundreds of degrees Celsius than any macroscopic heating method. To see why, consider the thermal conductance between the nanotube to the substrate. FIG. 1 shows an exemplary nanostructure sensing device 100, using a single nanotube. Device 100 comprises a nanotube 102, such as a carbon nanotube, disposed over a substrate 104, such as a silicon or other semiconductor substrate, or a non-conducting substrate. At least two conductive elements 106 are disposed over the substrate, and electrically connected to the nanotube. Devices which use a plurality of nanotubes may also be constructed.

The nanotube conducts along its length “L” with the thermal conductivity of graphite in-plane, 19.5 W/mK. For a nanotube of diameter “D” in nm and length “L” in um, the resulting conductance is 2×10-11 W/K D²/L. With 1.4 nm nanotubes and typical exposed lengths of about 0.5 um, this thermal conductance is 40 pW/K, a very small number. (Measuring this thermal conductivity is an interesting and difficult experiment that has been attempted by Philip Kim. (P. Kim, L. Shi, A. Majumdar, and P. L. McEuen, Phys. Rev. Lett. 87, 21 (01).) It is negligible compared to the thermal conductance from the tube directly to the substrate. We can estimate that the conductivity of the interface is not likely to be better than the conductivity of graphite perpendicular to its sheets, 0.057 W/mK. Roughly speaking the conductance of a nanotube of length L and diameter D, separated from the substrate by a thickness t in nm which is comparable to the graphite interlayer spacing, is 5.7×10-8 W/K DL/t. For typical numbers of D=1.4, L=0.5, t=0.3, this conductance is about 10 nW/K. This is an upper bound, and the actual conductance may be much smaller. An additional contribution of similar magnitude comes from conduction through the layer of water which is likely to surround nanotubes in air.

While the thermal conductance to remove heat from the nanotube is quite low, a significant amount of energy can be deposited in a nanotube. Currents of 10's of μA can be passed through a single tube with voltages of around a volt. The resulting power of 10's of μW is not all deposited in the nanotube. A significant fraction of it is deposited directly in the contacts. Any defect or other source of resistance in the nanotube will dissipate some of this heat, however, and the nanotube may get quite hot.

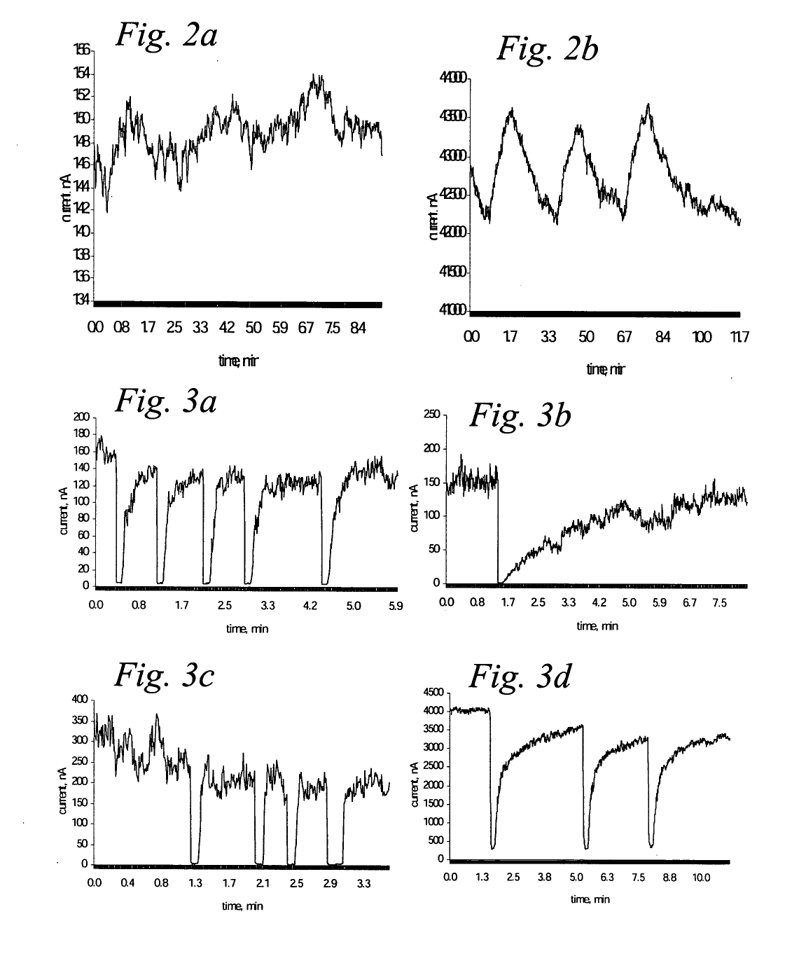

This heating effect has been successfully demonstrated. Surprisingly, it may be used to improve the response of nanostructure sensors. Two examples are demonstrated in FIGS. 2a-b and 3a-d. FIGS. 2a-b show the effect of ohmic heating to heat a section of a nanotube to the temperature necessary for sensing action. Conventional tin oxide (SnO2) sensors need to be heated to ˜300° C. for best operation. FIG. 2a shows the response of a SnO2 functionalized nanotube chemical sensor at 200° C. and low current (˜140 nA). FIG. 2b shows the response of the same device at a much higher current (˜43,000 nA). Ohmic heating due to the high current has increased the temperature of at least a portion of the nanotube to a typical operating temperature of about 300° C.

FIGS. 3a-d illustrate the effect of ohmic heating when used to regenerate a nanotube sensor. The performance of this sensor was found to deteriorate over several days, so that its recovery time after sensing became extremely long. FIGS. 3a and 3b show the original fast recovery and the degraded slow recovery, respectively. Heating on a hot plate to a high temperature causes the sensor to recover its initial behavior, as illustrated in FIG. 3c. The same result can be achieved by heating the nanotube ohmically, as illustrated in FIG. 3d. The ohmic heating requires only microwatts, which is much less than even the best micromachined hotplate.

It should be understood that the applications of this method are not limited to these two examples. There are many occasions on which it may be desirable to heat a nanotube device, both for sensors and for other applications. Temperatures between room temperature and 600° C. or more are readily achievable.

The palladium (Pd) coated carbon nanotubes as hydrogen sensors were described previously (Kong, J.; Chapline, M. G.; Dai, H. Adv. Mater. 2001, 13, 1384-1386), which is incorporated herein by reference. The published time for full recovery of the sensor was ˜400 seconds, which is in full agreement with our observations (6-7 minutes).

The palladium (Pd) coated carbon nanotubes are hydrogen sensors with fast response, high selectivity and reversibility under ambient conditions. We have found that the recovery time of the sensor, which is typically 6-7 minutes, can be decreased down to 5 seconds by heating the sensor in air. The sensor exhibits this fast recovery even after being cooled down to room temperature.

Heating of the Pd-coated carbon nanotube sensors as well as other sensors made from nanostructures can be accomplished by ohmic heating as described above, as well as by conventional macroscopic heating using an adjacent heat source such as a hot plate or micro-hotplate.

Having thus described a preferred embodiment of the nanotube device, it should be apparent to those skilled in the art that certain advantages of the within system have been achieved. It should also be appreciated that various modifications, adaptations, and alternative embodiments thereof may be made within the scope and spirit of the present invention. For example, particular configuration has been illustrated, but it should be apparent that the inventive concepts described above would be applicable to other configurations, such as those that employ a plurality of nanotubes. The invention is further defined by the following claims.

What is claimed is:

1. A nanostructure sensing device comprising:
a substrate, said substrate being at a temperature of less than 100° C.;
at least one nanostructure disposed over the substrate, said nanostructure being at a temperature of at least 100° C.; and
at least two conductive elements disposed over the substrate and electrically connected to the at least one nanostructure.

2. The device of claim 1, wherein the nanostructure comprises a nanotube.

3. The device of claim 1, wherein the nanostructure comprises a plurality of nanotubes.

4. The device of claim 1, wherein the nanostructure is maintained at a temperature of at least about 200° C.

5. The device of claim 1, wherein the nanostructure is maintained at a temperature of at least about 300° C.

6. The device of claim 5, wherein the nanostructure is maintained at an elevated temperature by passing a current of at least about 10 μA through the nanotube.
